(19) United States
(12) Patent Application Publication
(10) Pub. No.: US 2021/0014965 A1
(43) Pub. Date: Jan. 14, 2021

(54) HYBRID CARRIER BOARD AND MANUFACTURING METHOD, ASSEMBLY, AND OPTICAL MODULE THEREOF

(71) Applicant: InnoLight Technology (Suzhou) LTD., Suzhou (CN)

(72) Inventors: Xigui FANG, Suzhou (CN); Yuzhou SUN, Suzhou (CN); Xiangzhong WANG, Suzhou (CN)

(73) Assignee: InnoLight Technology (Suzhou) LTD.

(21) Appl. No.: 16/925,498

(22) Filed: Jul. 10, 2020

(30) Foreign Application Priority Data
Jul. 11, 2019 (CN) 201910622928.6
Feb. 10, 2020 (CN) 202010084973.3

(51) Int. Cl. H05K 1/02; H05K 1/11; H05K 3/46; H05K 1/18

(52) U.S. Cl. CPC H05K 1/0298; H05K 1/111; H05K 2201/068; H05K 1/181; H05K 3/4602

(57) ABSTRACT

A hybrid carrier board and a manufacturing method, an assembly, and an optical module thereof. The hybrid carrier board includes a PCB and a package substrate bonded to the PCB, the package substrate and the PCB being electrically connected. A surface of the package substrate is partially exposed outside of the PCB to form a packaging area adapted for bare die installation.

### CROSS-REFERENCE TO RELATED APPLICATION

This application is based upon and claims priority to Chinese Patent Application 201910622928.6, filed on Jul. 11, 2019, and Chinese Patent Application 202010084973.3, filed on Feb. 10, 2020. The entire contents of these applications are incorporated herein by reference.

### FIELD OF THE DISCLOSURE

The present application relates to the field of optical communication technology and, more particularly, to a hybrid carrier board and a manufacturing method, an assembly, and an optical module thereof.

### BACKGROUND

As the 5G era places a high demand on bandwidth for computation, transmission, and storage, and as silicon photonics technology matures, optical interconnect is being deployed on-board and board-to-board. The number of channels in an optical module is increasing significantly, and application-specific integrated circuits (ASIC) are used to control the operation of transceivers. The packaging of an optical module requires that an optical chip or an optical module be packaged together with an ASIC control chip to reduce the volume and increase interconnect density, thereby giving rise to the concept of optoelectronic co-packaging structure. In comparison with conventional design, where an optical module is located at an edge or a non-edge portion of a board, an optical module in an optoelectronic co-packaging structure offers advantages in terms of bandwidth, size, weight, and power consumption.

Currently, an optoelectronic co-packaging structure comes mostly in two forms. The first form integrates various optoelectronic chips and/or signal processor(s) onto a single substrate to form an assembly, and then mounts the assembly as a whole onto a PCB (printed circuit board) of a module by means of BGA (ball grid array) or wire bonding. The second form uses a chip technique, a ceramic substrate technique, or a package substrate technique to manufacture a package substrate at a module level to meet the requirement of high-precision lines for a flip-chip, and then flip-chip bonding or mounting all of the optoelectronic chips, control chips, etc. onto the package substrate. The first form results in a shortened high-speed link and higher radio frequency (RF) bandwidth in comparison with the conventional board-edge structure. However, the link from the chip to the package substrate and then to the PCB needs further improvement, and there is room for improvement in high frequency. The second form, despite having a simple and short high-speed link, is subject to major limitations in the manufacturing technique. First, the cost to make a package substrate in the size of a module is high. Second, to meet the requirement of precise lines for an optoelectronic flip-chip, the copper foil of the package substrate is made very thin, resulting in low peel strength and poor reliability for mounting electronic chips and plugging and unplugging via gold contact fingers. Third, for a module-level package substrate, the thickness of the package substrate increases and the yield of precise lines decreases as the number of layers increases.

### SUMMARY

Purposes of the present disclosure include providing a hybrid carrier board and a manufacturing method, an assembly, and an optical module thereof.

To achieve one of the aforementioned purposes, one embodiment of the present disclosure provides a hybrid carrier board including a printed circuit board (PCB) and a package substrate bonded to, and electrically connected with the PCB. A surface of the package substrate is partially exposed outside of the PCB to form a packaging area adapted for bare die installation.

Another embodiment of the present disclosure provides a method for manufacturing a hybrid carrier board, the method including the following steps:

manufacturing a package substrate, the package substrate including a dielectric layer and an electrically conductive layer;

forming a packaging area on a surface of the package substrate, the packaging area having formed thereon solder pads adapted for bare die installation;

providing a substack of the PCB;

laminating the package substrate and the substack of the PCB together and exposing the packaging area; and

manufacturing an electrically conductive via-hole to electrically connect the substack of the PCB and the package substrate.

### BRIEF DESCRIPTION OF THE DRAWINGS

FIG. 1 is a structural diagram of an optical module, according to an embodiment of the present disclosure;

FIG. 2 is an assembly diagram of an assembly including a carrier board and chips in the optical module shown in FIG. 1, according to an example embodiment of the present disclosure;

FIG. 3 is an assembly diagram of an assembly including a carrier board and chips in an optical module, according to another example embodiment of the present disclosure;

FIG. 4 is a diagram of a carrier board in an on-board optics (0130) optical module, according to an example embodiment of the present disclosure;

FIG. 5 is a structural diagram of a hybrid carrier board used for an optical module in an optoelectronic co-packaging structure, according to a first example embodiment of the present disclosure;

FIGS. 6 through 9 are diagrams of a method for manufacturing a hybrid carrier board used for an optoelectronic co-packaging structure, according to an example embodiment of the present disclosure;

FIG. 10 is a structural diagram of a hybrid carrier board used for an optoelectronic co-packaging structure, according to a second example embodiment of the present disclosure;

FIG. 11 is a diagram of a hybrid carrier board structure according to a variation of the second example embodiment of the present disclosure; and

FIG. 12 is a diagram of a hybrid carrier board structure according to another variation of the second example embodiment of the present disclosure.

### DETAILED DESCRIPTION

The text below provides a detailed description of the present disclosure with reference to specific embodiments illustrated in the attached drawings. However, these embodiments do not limit the present disclosure; the scope of protection for the present disclosure covers changes made to the structure, method, or function by persons having ordinary skill in the art on the basis of these embodiments.

In order to facilitate the presentation of the drawings in the present disclosure, the sizes of certain structures or portions have been enlarged relative to other structures or portions; therefore, the drawings in the present application are only for the purpose of illustrating the basic structure of the subject matter of the present application.

Additionally, terms in the text indicating relative spatial position, such as “upper,” “above,” “lower,” “below,” and so forth, are used for explanatory purposes in describing the relationship between a unit or feature depicted in a drawing with another unit or feature therein. Terms indicating relative spatial position may refer to positions other than those depicted in the drawings when a device is being used or operated. For example, if a device shown in a drawing is flipped over, a unit which is described as being positioned “below” or “under” another unit or feature will be located “above” the other unit or feature. Therefore, the illustrative term “below” may include positions both above and below. A device may be oriented in other ways (rotated 90 degrees or facing another direction), and descriptive terms that appear in the text and are related to space should be interpreted accordingly. When an element or layer is said to be “above” another component or layer or “connected to” another component or layer, it may be directly above the other component or layer or directly connected to the other component or layer, or there may be an intermediate element or layer.

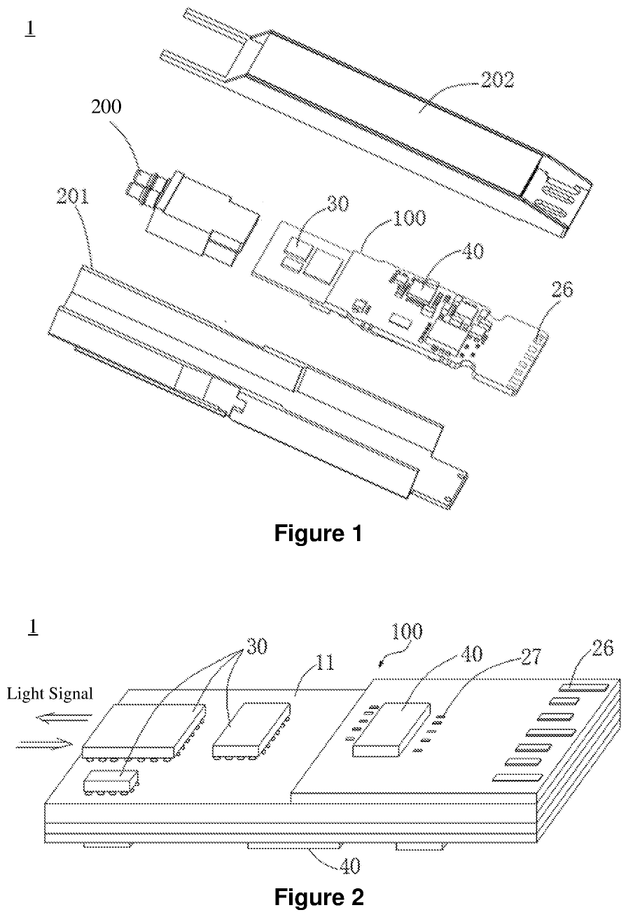

FIG. 1 is a structural diagram of an optical module 1, according to an embodiment of the present disclosure. FIG. 2 is an assembly diagram of an assembly in the optical module 1 of FIG. 1, according to an embodiment of the present disclosure. As illustrated in FIGS. 1 and 2, the optical module 1 using an optoelectronic co-packaging structure includes a housing, an optical interface 200 disposed at one end of the housing, at least one bare die 30, at least one surface-mount component 40, and a carrier board 100 disposed in the housing. The housing includes an upper housing 202 and a lower housing 201. The carrier board 100 includes a PCB, as well as a packaging area 11, surface-mount solder pads 27, and an electrical interface 26 disposed on the PCB. During assembly, the at least one bare die 30 is installed onto the packaging area 11 of the carrier board 100 by means of flip-chip technology. For illustrative purposes, FIGS. 1 and 2 show three bare dies 30 installed onto the packing area 11. The surface-mount component 40 (“SMC”) is mounted onto the surface-mount solder pads 27 of the carrier board 100. The bare die 30 and the surface-mount component 40 are both installed on the carrier board 100 to form an assembly, and then the assembly is installed in the housing. The surface-mount component 40 usually includes a packaged electronic chip, resistor, or capacitor, etc. When using a bare die as the surface-mount component, the bare die 30 needs to be processed to adapt to actual applications, such as matching the pitch of solder pads of the bare die with the pitch of surface-mount solder pads. The packaged surface-mount component 40 is mounted onto the surface-mount solder pads 27 by using a common mounting technology, which will not be described in detail here. The electrical interface 26 of the PCB is used as a pluggable electrical interface for the optical module 1, and usually includes gold contact fingers that are disposed on upper and lower surfaces of one end of the carrier board 100. The electrical interface 26 of the PCB may alternatively be an interface for connecting to another circuit board such as a flexible circuit board. The aforementioned bare die 30 may be an unpackaged semiconductor chip and may include a photonic integrated circuit (PIC) as well as one or a combination of more than one of a digital signal processor (DSP), a driver (DRV), a trans-impedance amplifier (TIA), etc. Here, the photonic integrated circuit may be an integrated chip that integrates a laser, a detector, a modulator, and a waveguide. Alternatively, the photonic integrated circuit may be an integrated circuit that integrates a waveguide and a modulator, while a laser and a detector are configured separately from the photonic integrated circuit. The separately configured laser and detector may be a laser and a detector that are commonly used in a conventional optical module, or may be formed as bare dies that are installed onto the aforementioned packaging area 11 by means of flip-chip technology. The aforementioned surface-mount component 40 may be a packaged semiconductor chip such as a microprocessor, a memory, an application-specific integrated circuit, etc. One or more electronic components such as a resistor or a capacitor may be disposed on the PCB. Solder pads are disposed on the aforementioned packaging area 11, and the pitch between these solder pads matches the pitch between solder pads on the aforementioned bare die 30. Usually, the center-to-center distance (i.e., the “pitch”) between the solder pads on the packaging area 11 is less than or equal to 150 μm and is very precise. The surface-mount solder pads 27 and the electrical interface 26 are manufactured with a common PCB fabrication technique and have high peel strength and high plugging and unplugging reliability.

Light received by the optical module 1 enters the bare die 30 (e.g., a PIC or a photodetector) and is then converted to an electrical signal, which is transmitted from the bare die 30 to a trans-impedance amplifier (TIA) directly through an internal trace of the packaging area 11. Next, the electrical signal is transmitted through the internal trace of the packaging area 11 to a high-speed trace or the surface-mount solder pads 27 and to the surface-mount component 40 mounted on the surface-mount solder pads 27. The electrical signal is then transmitted through a trace of the PCB to the gold contact fingers, and from the gold contact fingers to an external circuit or processor. Similarly, an electrical signal received by the gold contact fingers is transmitted through the trace of the PCB to the surface-mount component 40, which interprets the electrical signal before the electrical signal is transmitted through the surface-mount solder pads 27 and the high-speed trace of the PCB to the packaging area 11. The electrical signal is transmitted through the packaging area 11 to a driver to drive the bare die 30 (e.g., a laser chip or a photonic integrated circuit) to operate, and then the bare die 30 converts the electrical signal to an optical signal for output. The driver may be a bare die installed on the packaging area 11 by means of flip-chip technology. Alternatively, the bare die 30 may process the optical signal by, for example, modulating, amplifying, splitting, or combining the optical signal, before transmitting the optical signal. Since the bare die 30 is directly installed onto the packaging area 11 of the carrier board 100 by means of flip-chip technology, the bare die 30 and the carrier board 100 are connected via a high-speed link which is simple and short. Therefore, a host/line side link is concise so that a high-frequency bandwidth may be effectively increased and optimal performance at high-speed may be achieved. The aforementioned specific embodiment is simply used as an example to describe signal transmission. In another example embodiment, the bare die 30 on the packaging area 11 may include one or a combination of more than one of a photonic integrated circuit, a digital signal processor, a driver, a trans-impedance amplifier, etc., or may also be an integrated chip including one or more of the foregoing. Regardless of the combination, signal transmission between the bare die 30 and the carrier board 100 is achieved directly through the solder pads in the packaging area 11 to provide the simple and short high-speed link. The bare die 30 and the electronic components are both installed on one carrier board 100, and each electronic chip or optoelectronic chip may be formed as a bare die that is directly installed on the carrier board 100. Therefore, the area of the carrier board 100 can be effectively reduced, thus significantly increasing the level of integration for the optical module 1.

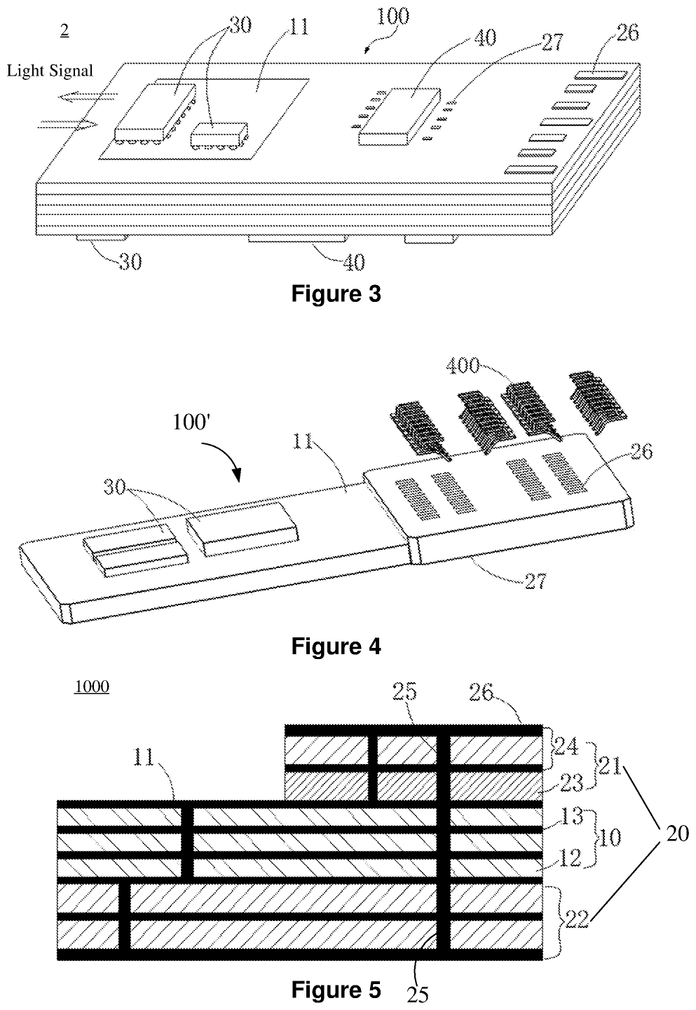

In the embodiment illustrated in FIG. 2, the packaging area 11 is disposed at the upper surface or lower surface of the carrier board 100. Alternatively, as illustrated in FIG. 3, which is an assembly diagram of an optical module 2 according to another example embodiment of the present disclosure, the packaging area 11 may be disposed at both the upper and lower surfaces of the carrier board 100. In other words, the bare dies 30 may be installed on the upper surface or the lower surface of the carrier board 100 by means of flip-chip technology, or some of the bare dies 30 may be mounted on the upper surface and some mounted on the lower surface of the carrier board 100 by means of flip-chip technology. Similarly, the surface-mount solder pads 27 for mounting the surface-mount components 40 may be disposed on both the upper and lower surfaces of the carrier board 100, or all of the surface-mount solder pads 27 may be disposed on one of the upper and lower surfaces of the carrier board 100. The optical module 2 integrates the surface-mount component 40 and the bare die 30 on one carrier board 100. The carrier board 100 has a high-precision trace area, which is the packaging area 11, adapted for the installation of the bare die 30 by means of flip-chip technology. The optical module 2 also has a PCB (printed circuit board) that has a high peel strength and a high plugging and unplugging reliability. The cost is relatively low, and the height (thickness) of a package assembly as a whole is relatively small, thus enabling further improvement in the level of integration for the optical module 2.

The aforementioned bare die 30 is directly installed on the packaging area 11 by means of flip-chip technology. In another example embodiment, the bare die 30 may be installed directly on the packaging area 11 by means of wire bonding.

In the example embodiment illustrated in FIG. 3, the electrical interface 26 of the carrier board 100 used in the optical module 2 includes gold contact fingers. In another example embodiment, another type of electrical interface may be used. As illustrated in FIG. 4, which is a diagram of a carrier board 100′ in an onboard optics (0130) optical module according to an embodiment of the present disclosure, an electrical interface 26 of the carrier board 100′ includes electrical contact pads to electrically connect to an external connector 400. The electrical contact pads (the electrical interface 26) may be disposed on one surface of the carrier board 100′, and surface-mount solder pads 27 are disposed on a surface of the carrier board 100′ opposite to the electrical contact pads. Alternatively, the electrical contact pads may be separately disposed on the upper and lower surfaces of the carrier board 100′.

In the aforementioned optical modules 1 and 2 using an optoelectronic co-packaging structure, the bare die 30 of the optical module may be directly installed on the PCB by means of flip-chip technology or wire bonding, provided that the pitch between the solder pads of the bare die is designed to match the pitch between the solder pads on the PCB. As a result, the host/line side link of the optical module is concise, the performance of the high-speed link is optimal, and the cost of the whole optical module is low. Alternatively, according to an embodiment of the present disclosure, a hybrid carrier board that integrates a package substrate and a PCB may be used. Details of the hybrid carrier board are described below.

In the following example embodiment, a detailed description of a hybrid carrier board used in the aforementioned optical module using an optoelectronic co-packaging structure is provided. The hybrid carrier board includes a PCB and a package substrate bound to the PCB, the package substrate and the PCB being electrically connected. A surface of the package substrate is partially exposed outside of the PCB to form a packaging area, and the packaging area is adapted for bare die installation. The manufacturing process of the hybrid carrier board combines manufacturing techniques for package substrates and PCBs. The package substrate and the PCB are laminated together so that some areas of the hybrid carrier board have high precision traces and are capable of meeting the requirements for packaging an optoelectronic bare die, while other areas of the hybrid carrier board have high peel strength and high plugging and unplugging reliability. At the same time, the hybrid carrier board has a simple and short high-speed link, which increases high-frequency bandwidth effectively and lowers the cost. Here, the package substrate refers to a substrate that is manufactured using an integrated circuit substrate manufacturing technique. In other words, the package substrate is an IC carrier board. Here, the integrated circuit substrate manufacturing technique includes substrate-like PCB (SLP) technology, or ceramic substrate technology, etc. For example, the package substrate may be manufactured using one or more of the following techniques: a full additive process, a semi-additive process (SAP), and a modified semi-additive process (MSAP), etc., and may be adapted for integrated circuit packaging. A fine trace layer may be formed on a surface of the package substrate using a copper build-up process to meet the requirement for high-precision traces for bare die installation.

### First Example Embodiment

FIG. 5 is a structural diagram of a hybrid carrier board 1000 used as the carrier board 100 in the optical module 1 illustrated in FIG. 2, according to a first example embodiment of the present disclosure. As illustrated in FIGS. 2 and 5, in the first example embodiment, the hybrid carrier board 1000 used for the optical module 1 using an optoelectronic co-packaging structure includes a PCB 20 and a package substrate 10 that are laminated together, the package substrate 10 and the PCB 20 being electrically connected. The PCB 20 includes a first substack 21 and a second substack 22. The first substack 21 and the second substack 22 are laminated to an upper surface and a lower surface of the package substrate 10, respectively. In another example embodiment, the PCB 20 may include only one substack, which is laminated to one surface of the package substrate 10. The first substack 21 and/or the second substack 22 of the PCB 20 has disposed on it a window to expose a portion of the upper surface and/or lower surface of the package substrate 10 to serve as a packaging area 11. The packaging area 11 is adapted for the installation of the bare die 30, such as a photonic integrated circuit, a digital signal processor, a driver, a trans-impedance amplifier, a laser chip, and/or a photodetector, etc. The packaging area 11 is a portion of a surface of the package substrate 10. Solder pads are disposed on the packaging area 11, and the pitch of these solder pads matches the pitch of solder pads of the bare die 30 that is to be installed. Usually, the solder pads on the packaging area 11 have a center-to-center distance (i.e., “pitch”) that is less than or equal to 150 μm and is very precise in order to meet the requirement for high-precision traces for bare die installation. The surface-mount solder pads 27 and the electrical interface 26 of the hybrid carrier board 1000 are disposed on a surface of the PCB 20. The surface-mount solder pads 27 are adapted for installing the surface-mount component 40, which includes a packaged semiconductor chip, such as a microprocessor, a memory, or an application-specific integrated circuit, or an electronic component, such as a resistor or a capacitor. The surface-mount solder pads 27 are included in a surface trace layer of the PCB 20. The surface trace layer is commonly included in a conventional PCB, and has high peel strength and high plugging and unplugging reliability. Therefore, the surface-mount solder pads 27 can meet the peel strength requirement for surface mounting.

In the first example embodiment, an electrically conductive via-hole 25 is configured in each of the first substack 21 and the second substack 22 of the PCB 20. The PCB 20 and the package substrate 10 are electrically connected by the electrically conductive via-holes 25. As a result, the hybrid carrier board 1000 has a concise high-speed link with optimal performance, a high-frequency bandwidth, and a relatively low cost. The aforementioned package substrate 10 includes a number of insulating dielectric layers 12 and electrically conductive layers 13. Various semiconductor materials used in bare dies have a coefficient of thermal expansion (CTE) smaller than the coefficients of thermal expansion of materials commonly used in insulating layers of conventional PCBs. In order to match the coefficient of thermal expansion of the bare die 30 and to increase binding reliability for the installation of the bare die 30, the insulating dielectric layers 12 of the package substrate 10 are formed of a material with a coefficient of thermal expansion smaller than that of the materials commonly used for insulating layers in conventional PCBs so that the coefficients of thermal expansion of the dielectric layers 12 can be as close to that of the bare die 30 as possible. For example, the insulating dielectric layers 12 may be formed of a material with a coefficient of thermal expansion in a horizontal direction smaller than or equal to 10 ppm/° C., and the material may include ceramic, glass, Bismaleimide Triazine (BT) resin, BT-like resin, or silicon, etc. In another example embodiment, the PCB 20 may be formed of the same material that is used for forming the insulating dielectric layers 12 of the package substrate 10. For example, both of the insulating dielectric layers 12 of the package substrate 10 and the PCB 20 may be formed of BT resin or BT-like resin so that the package substrate 10 and the PCB 20 have the same coefficient of thermal expansion, resulting in higher reliability of the hybrid carrier board 1000 and increased stiffness of the PCB 20, which leads to better reliability of a final product. Meanwhile, the package substrate 10 is manufactured using an integrated circuit substrate manufacturing technique and has a precise trace layer. The PCB 20 is manufactured using a common PCB manufacturing technique, and has a relatively thick copper layer. Thus, the surface trace layer of the PCB 20 has high peel strength and high plugging and unplugging reliability.

In the first example embodiment, as illustrated in FIG. 5, the package substrate 10 is a relatively thin electrically conductive BT (bismaleimide triazine) board that is manufactured using a modified semi-additive process (MSAP). A first trace layer and solder pads are disposed on the packaging area 11 of the package substrate 10. The center-to-center distance (i.e., pitch) between the solder pads on the packaging area 11 is less than or equal to 150 μm and matches the pitch between the solder pads of the bare die. This design is capable of meeting the requirement for high-precision traces for bare die installation, so that the hybrid carrier board 1000 can be used for packaging. In the first example embodiment, the material used for the insulating dielectric layer 12 includes BT resin or BT-like resin. In another example embodiment, the material used for the insulating dielectric layer 12 may be ceramic, glass, or silicon, etc. The insulating dielectric layers 12 and the electrically conductive layers 13 together make an electrically conductive ceramic substrate, a glass substrate, or a silicon substrate. In other words, the package substrate 10 may be an electrically conductive BT substrate, BT-like substrate, ceramic substrate, glass substrate, or silicon substrate. The coefficient of thermal expansion of the silicon substrate or a BT board is close to that of the bare die 30 such as an optoelectronic chip, a photonic integrated circuit chip, etc., resulting in better binding stability for bare die installation and higher product reliability. When BT resin or BT-like resin is used to manufacture the package substrate 10, the electrically conductive via-holes 25 formed in the first substack 21 and the second substack 22 of the PCB 20 may extend through the PCB 20 and the package substrate 10. When silicon, ceramic, or glass is used to manufacture the package substrate 10, an electrically conductive connection pad may be configured on both of the upper and lower surfaces of the package substrate 10 that is laminated between the first substack 21 and the second substack 22 of the PCB 20. The electrically conductive via-holes 25 formed in the first substack 21 and the second substack 22 of the PCB 20 may extend through the first substack 21 and the second substack 22 of the PCB 20 and be connected to the electrically conductive connection pads on the upper and lower surfaces of the package substrate 10, thereby achieving electrical connection between the PCB 20 and the package substrate 10.

Surface-mount technique (SMT) may be used for mounting the surface-mount component 40 on the PCB 20. In the first example embodiment, the first substack 21 and the second substack 22 of the PCB 20 each includes a core layer 24 and a prepreg layer 23 (which is a sheet of pre-impregnated material). In FIG. 5, only the core layer 24 and the prepreg layer 23 of the first substack 21 on top of the package substrate 10 are labeled, and only one core layer 24 and one prepreg layer 23 are illustrated. The second substack 22 below the package substrate 10 may have a structure that is the same as or different from the structure of the first substack 21, and the quantities of the core layer 24 and the prepreg layer 23 may be adjusted as needed. The core layer 24 here refers to Copper Clad Laminate (CCL), including a base material plate (i.e., the insulating layer of the PCB) and a copper cladded on one or two surfaces of the base material plate. In another example embodiment, the first substack 21 and the second substack 22 of the PCB 20 may each include one or more copper layers and prepreg layers laminated together, or a combination of copper, prepreg, and core layers. The copper formed using the PCB manufacturing technique is relatively thick, and the peel strength between the copper and the base material plate of the core layer 24 is high. The surface-mount solder pads 27 and gold contact fingers included in the electrical interface 26 are formed of the copper layer on the PCB 20. As a result, the binding reliability of the surface mount component 40 is high, and the plugging and unplugging reliability of the gold contact fingers included in the electrical interface 26 is also high. Consequently, the problem of the package substrate 10 being unable to meet the high peel strength requirement for surface mount components and the problem of poor plugging and unplugging reliability of the gold contact fingers are overcome.

The size and position of the packaging area 11 may be configured according to actual needs. For example, one end of the hybrid carrier board 1000 may be used as the packaging area 11, as in the embodiment illustrated in FIG. 2. Alternatively, a middle area at one end of the hybrid carrier board 1000 may be used as the packaging area 11, as illustrated in FIG. 3. The packaging area 11 may also be disposed on the lower surface of the package substrate 10. Moreover, the packaging area 11 may be disposed on both the upper and lower surfaces of the package substrate 10. Accordingly, corresponding windows are disposed on the substacks 21 and 22 of the PCB 20 respectively laminated onto the upper and lower surfaces of the package substrate 10 to expose the packaging area 11.

In the first embodiment of the present disclosure, the package substrate 10 of the hybrid carrier board 1000 used for the optical module 1 using the optoelectronic co-packaging structure is manufactured by using a package substrate technology, such as a substrate-like PCB (SLP) technology or a ceramic substrate technology, i.e., a semi-additive process (SAP) or a modified semi-additive process (MSAP), to make the package substrate 10 according to the precision requirements for bare die installation, with thinner thickness and fewer layers. The surface of the package substrate 10 partially serves as the packaging area 11, and the other portion of the surface serves as a connection area. The packaging area 11 is used for the installation of bare dies such as an optoelectronic chip and/or a photonic integrated circuit chip, and the connection area is used for PCB lamination.

Specifically, the method for manufacturing the hybrid carrier board 1000 includes the following steps.

First, the package substrate 10 is manufactured. The package substrate 10 includes one or more insulating dielectric layers 12 and one or more electrically conductive layers 13 stacked together. The number of the insulating dielectric layers 12 and the number of the electrically conductive layers 13 may be adjusted as needed. When there are a plurality of electrically conductive layers 13, all electrically conductive layers 13 may be electrically connected by means of an electrically conductive via-hole. In another example embodiment, the electrical connection between the plurality of electrically conductive layers 13 may be achieved by means of sidewall plating.

Next, the packaging area 11 is formed on a surface of the package substrate 10. The packaging area 11 has the first trace layer, which includes solder pads adapted for bare die installation. The PCB 20 having one or more substacks is provided. In the first example embodiment, the PCB 20 includes the first substack 21 and the second substack 22.

The package substrate 10 and the substack of the PCB 20 are laminated together, exposing the aforementioned packaging area 11. In the first example embodiment, the first substack 21 and the second substack 22 of the PCB 20 are laminated onto the upper surface and the lower surface of the package substrate 10, respectively. The first substack 21 and/or the second substack 22 of the PCB 20 has manufactured thereon a window that corresponds to the aforementioned packaging area 11 to expose the packaging area 11.

The electrically conductive via-holes 25 are formed in the first substack 21 and the second substack 22 of the aforementioned PCB 20, and in the package substrate 10. The electrically conductive via-holes 25 are used to electrically connect the PCB 20 and the package substrate 10. The electrically conductive via-holes 25 formed in the first substack 21 and the second substack 22 of the PCB 20 may extend through the PCB 20 and the package substrate 10. A second trace layer and the electrical interface 26 are formed on the surface of the PCB 20.

The aforementioned method for manufacturing the package substrate 10 includes a semi-additive process (SAP) or a modified semi-additive process (MSAP). A ceramic substrate, a silicon substrate, a glass substrate, a BT-like board, or a BT board, etc., is made according to the precision requirement for bare die installation, with thinner thickness and fewer layers.

When laminating the first substack 21 and the second substack 22 of the PCB 20 to the upper and lower surfaces of the package substrate 10, respectively, a window may be formed on the first substack 21 and/or the second substack 22 either after or before the lamination. Specifically, two manufacturing methods are described below.

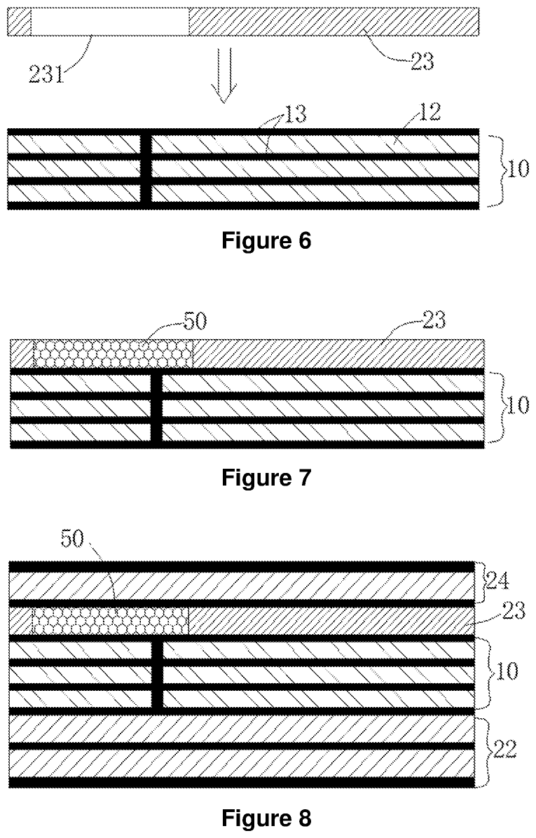

As illustrated in FIGS. 6 through 9, the aforementioned method for laminating the first substack 21 and the second substack 22 of the PCB 20 to the upper surface and the lower surface of the package substrate 10, respectively may include the following steps.

First, as illustrated in FIG. 6, the prepreg layer 23 of the first substack 21 is provided, and a first window 231 is formed in the prepreg layer 23. The position and the size of this first window 231 correspond to the position and the size of the packaging area 11. That is, the first window 231 is positioned above the packaging area 11, and the size of the first window 231 is the same as, or slightly greater than, the size of the packaging area 11.

As illustrated in FIG. 7, the aforementioned prepreg layer 23 is stacked on the upper surface or the lower surface of the package substrate 10. A release film 50 is filled in the first window 231.

As illustrated in FIG. 8, the core layer 24 of the first substack 21 and the second substack 22 of the PCB 20 are provided. The core layer 24 is laminated onto the prepreg layer 23, and the second substack 22 is laminated to the lower surface of the package substrate 10. In this example embodiment, the first substack 21 includes a core layer 24 and a prepreg layer 23 (which is a sheet of pre-impregnated material). In FIG. 5, only the core layer 24 and the prepreg layer 23 of the first substack 21 on top of the package substrate 10 are labeled, and only one core layer 24 and one prepreg layer 23 are illustrated. In another embodiment, the first substack 21 and the second substack 22 of the PCB 20 may each include more than one core layer 24 and prepreg layer 23.

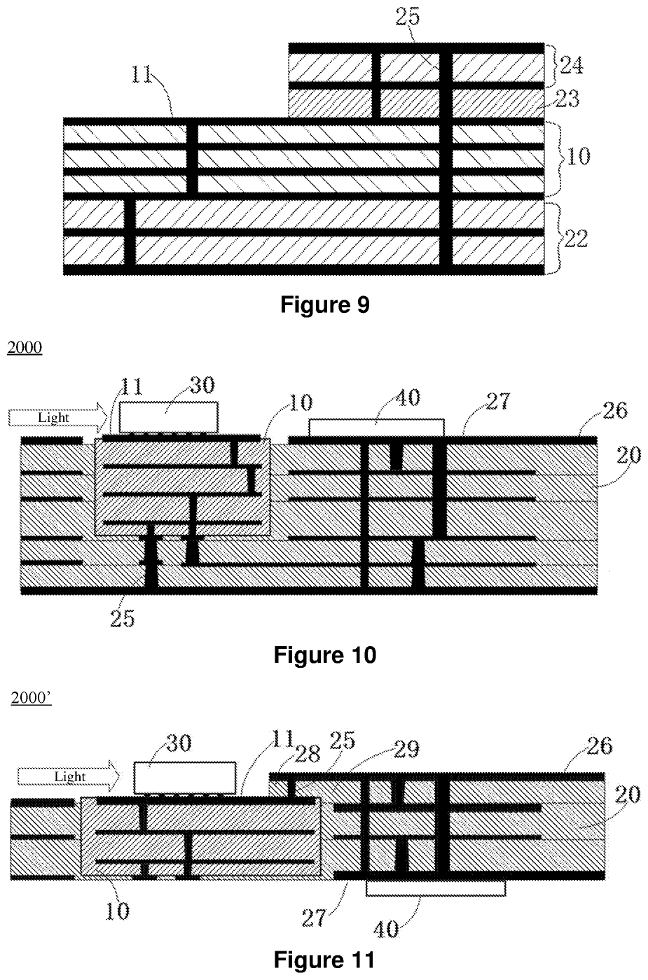

Next, a second window (not illustrated) is formed in the core layer 24 of the first substack 21, The position and the size of the second window are the same as those of the first window 231. The release film 50 is then removed to expose the packaging area 11, as illustrated in FIG. 9. Here, the method for manufacturing the second window may employ a controlled deep milling technology.

The aforementioned step of laminating the first substack 21 and the second substack 22 of the PCB 20 to the upper surface and the lower surface of the package substrate 10, respectively, may also use the following method.

First, the prepreg layer 23 is provided. The first window 231 is formed in the prepreg layer 23. The position and the size of the first window 231 correspond to the position and the size of the aforementioned packaging area 11.

The aforementioned prepreg layer 23 is stacked on the upper surface or the lower surface of the package substrate 10. The release film 50 is filled in the first window 231.

The core layer 24 of the first substack 21 and the second substack 22 of the PCB 20 are provided. The second window is formed in the core layer 24. The position and the size of the second window are the same as those of the aforementioned first window 231.

The core layer 24 is laminated onto the aforementioned prepreg layer 23.

The release film 50 is removed to expose the packaging area 11.

In another embodiment, the first window 231 of the prepreg layer 23 and the second window of the core layer 24 may be formed in advance. Then, the prepreg layer 23 with the pre-formed first window is laminated on the package substrate 10, and the release film 50 is filled in the first window 231. Next, the core layer 24 with the pre-formed second window is laminated onto the prepreg layer 23. Finally, the release film 50 is removed to expose the packaging area 11.

In another example embodiment, the PCB 20 may include only one substack, which is laminated to one surface of the package substrate 10. When the packaging area 11 is disposed on the surface of the package substrate 10 facing toward the substack of the PCB 20, the method for laminating the package substrate 10 to the substack of the PCB 20 is the same as the method above. When the packaging area 11 is disposed only on the surface of the package substrate 10 facing away from the substack of the PCB 20, the substack of the PCB 20 may be directly laminated to the package substrate 10 without a window.

The prepreg layer 23 in all of the manufacturing methods above is a low-flow pre-preg (PP), also referred to in some cases as “No-Flow” prepreg. When being laminated under heat, the low-flow PP has a relatively low flowability. Additionally, the release film 50 plays a supporting and protecting role, preventing the low-flow adhesive from flowing onto the packaging area 11. The size of the connection area of the package substrate 10 is designed according to the capability of the PCB manufacturing technique. The surface of the PCB 20 undergoes surface treatment, such as solder masking, which is commonly included in the PCB manufacturing process. As a finely engineered installation area for bare die installation, the packaging area 11 has precise traces for the installation of one or more bare die 30 such as an optoelectronic chip or a photonic integrated circuit chip. The PCB 20 possesses common PCB functions, i.e, the SMT and gold contact finger functions. As result, the optoelectronic co-packaging hybrid carrier board 1000 has highly precise traces in a local area and high peel strength and high plugging and unplugging reliability in other areas. In the carrier board 1000, the high-speed link between the PCB 20 and the package substrate 10 is simple and short, thereby increasing high-frequency bandwidth effectively and lowering the cost.

### Second Example Embodiment

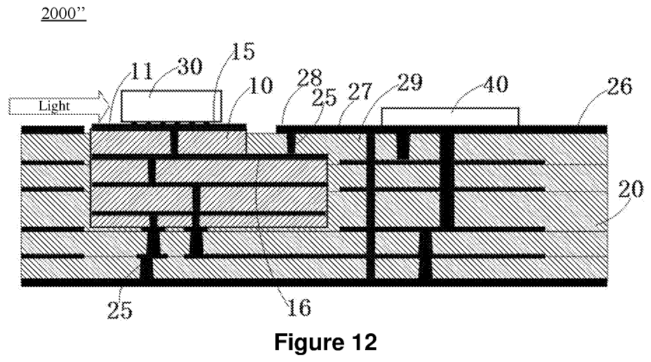

FIG. 10 is a structural diagram of a hybrid carrier board 2000 according to a second example embodiment of the present disclosure. FIG. 11 is a diagram of a hybrid carrier board structure 2000′ according to a variation of the second example embodiment of the present disclosure. FIG. 12 is a diagram of a hybrid carrier board structure 2000″ according to another variation of the second example embodiment of the present disclosure. As illustrated in FIGS. 10 through 12, according to the second example embodiment of the present disclosure, an optical module using an optoelectronic co-packaging structure may use a hybrid carrier board 2000, 2000′, or 2000″ that includes a PCB 20 and a package substrate 10 disposed in the PCB 20. The package substrate 10 includes electrically conductive traces. The electrically conductive traces and the PCB 20 are electrically connected. The surface of the package substrate 10 is at least partially exposed outside of the PCB 20 to serve as a packaging area 11 used for the installation of a bare die 30 such as a digital signal processor, a driver, a trans-impedance amplifier, an optoelectronic chip, and/or a photonic integrated circuit chip, etc. An accommodating space is disposed in the PCB 20, and the package substrate 10 is disposed in the accommodating space. The accommodating space includes at least one opening that extends through one surface of the PCB 20 so that the surface of the package substrate 10 is at least partially exposed outside of the PCB 20 to serve as the aforementioned packaging area 11. The coefficient of thermal expansion (CTE) of the package substrate 10 is smaller than, or equal to, the coefficient of thermal expansion (CTE) of the PCB 20, and is close to the coefficient of thermal expansion of a semiconductor chip such as a photonic integrated circuit chip. For example, the coefficient of thermal expansion in the horizontal direction of the package substrate 10 may be smaller than or equal to 10 ppm/° C. The package substrate 10 is, for example, an electrically conductive silicon substrate, an electrically conductive ceramic substrate, an electrically conductive glass substrate, or an electrically conductive BT board, and is free from the problem of poor reliability caused by a mismatch between the coefficients of thermal expansion of the PCB and the bare die. As a result, binding stability for bare die installation is good, and product reliability is high.

In the second example embodiment, the package substrate 10 is a relatively thin electrically conductive silicon substrate that is manufactured using a modified semi-additive process (MSAP). A first trace layer is disposed at the packaging area 11, and solder pads are formed on the first trace layer. The center-to-center distance (i.e., pitch) between the solder pads on the packaging area 11 is smaller than or equal to 150 μm and matches the pitch between the solder pads of the bare die 30 that is to be installed. This design is capable of meeting the requirement for high-precision traces for bare die installation, and provides a package function. Additionally, surface-mount technology (SMT) is usually used for mounting the surface-mount component 40 on the PCB 20. In the second example embodiment, the PCB 20 includes a number of core layers and prepreg layers. The core layer includes a base material plate and copper cladded on one or two surfaces of the base material plate. In another example embodiment, the PCB 20 may include one or more copper layers and prepreg layers laminated together, or a combination of copper, prepreg, and core layers. Using a PCB manufacturing technique, the copper is relatively thick, and the peel strength between the copper and the base material plate is high. As a result, the binding reliability of the surface-mount component 40 is high, and the plugging and unplugging reliability of the gold contact fingers (electrical interface) is also high. The peel strength of the surface trace layer of the PCB meets the peel strength requirement for surface mounting. Consequently, the problem of the package substrate 10 being unable to meet the high peel strength requirement for surface mounting and the problem of poor plugging and unplugging reliability of the gold contact fingers are overcome.

The package substrate 10 includes a number of insulating dielectric layers and electrically conductive layers. The electrically conductive layers are electrically connected by means of electrically conductive via-holes. In another example embodiment, electrical connection between the electrically conductive layers may be achieved by means of sidewall plating, i.e., the sidewall of the package substrate is plated to electrically connect the electrically conductive layers. The package substrate 10 may be formed as a cuboid or a step block and may be embedded in the PCB 20. A portion of a substack of the PCB 20 is laminated to at least a portion of a bottom surface of the package substrate 10 or at least a portion of an upper surface of the package substrate 10. An electrically conductive via-hole 25 may be disposed at the location where the substack of the PCB 20 is laminated to the package substrate 10. The electrically conductive via-hole 25 electrically connects the PCB 20 to the package substrate 10. In the second example embodiment, the substack of the PCB 20 includes one or more core layers and prepreg layers. In another example embodiment, the substack of the PCB 20 may include one or more copper layers and prepreg layers laminated together, or a combination of copper layers, prepreg layers, and core layers.

Specifically, as illustrated in FIG. 10, the accommodating space of the PCB 20 used for the embedding of the package substrate 10 is an open slot. The open slot may be a blind slot that includes a slot bottom and a slot sidewall. The package substrate 10 and the slot bottom of the open slot are laminated together. An electrically conductive via-hole 25 that electrically connects to the package substrate 10 is disposed at the slot bottom of the open slot of the PCB 20. At the same time, the PCB 20 may further include a connection portion extending from the PCB 20 at the upper surface of the package substrate 10, i.e., at the slot opening (the opening of the accommodating space). The connection portion is laminated onto a portion of the upper surface of the package substrate 10 to expose another portion of the upper surface of the package substrate 10 to serve as the packaging area 11. The connection portion may include a second electrically conductive via-hole disposed thereon to electrically connect the PCB 20 and the package substrate 10.

As illustrated in FIG. 10, when manufacturing the hybrid carrier board 2000, the package substrate 10 and the PCB 20 are provided. Solder pads are manufactured on the upper surface of the package substrate 10 so that the upper surface can serve as the packaging area 11. One or more electrically conductive connection pads are manufactured on the lower surface of the package substrate 10. The solder pads and the electrically conductive connection pads are electrically connected. An open slot is formed in the PCB 20. The aforementioned package substrate 10 is laminated into the open slot. The electrically conductive via-hole 25 is manufactured at the slot bottom of the open slot. The electrically conductive via-hole 25 and the electrically conductive connection pad on the lower surface of the package substrate 10 are connected, thereby achieving electrical connection between the package substrate 10 and the PCB 20. Chip solder pads are manufactured on the PCB 20 to serve as surface-mount solder pads 27. Gold contact fingers are manufactured on the PCB 20 to serve as the electrical interface 26. The chip solder pads are used for the installation of the surface-mount component 40.

In the hybrid carrier board 2000′ according to the variation of the second example embodiment illustrated in FIG. 11, the accommodating space includes an upper opening and/or a lower opening that extend through the upper surface and/or the lower surface of the PCB 20, respectively. As illustrated in FIG. 11, the package substrate 10 is disposed in the accommodating space. The PCB 20 includes a connection portion 28 extending from the PCB 20 to the upper surface (corresponding to the location of the upper opening of the accommodating space) and/or the lower surface (corresponding to the location of lower opening of the accommodating space) of the package substrate 10. The connection portion 28 of the PCB 20 is laminated to a portion of the upper surface and/or a portion of the lower surface of the package substrate 10 to expose a portion of the upper surface and/or a portion of the lower surface of the package substrate 10 to serve as the packaging area 11. The connection portion 28 has one or more electrically conductive via-holes 25 disposed to electrically connect the PCB 20 to the package substrate 10.

The manufacturing process of the hybrid carrier board 2000′ illustrated in FIG. 11 is described as follows. The package substrate 10 and a PCB 20 are provided. Solder pads are manufactured on a portion of the upper surface of the package substrate 10 to serve as the packaging area 11. An electrically conductive connection pad is manufactured on another portion of the upper surface of the package substrate 10. The solder pads and the electrically conductive connection pad are electrically connected. An accommodating space is formed in the PCB 20. The aforementioned package substrate 10 is laminated into the accommodating space such that the upper surface of the package substrate 10 is even with the upper surface of the PCB 20. The connection portion 28 is manufactured on the upper opening of the accommodating space such that the connection portion 28 covers the electrically conductive connection pad on the surface of the package substrate 10. The electrically conductive via-hole 25 is formed in the connection portion 28 such that the electrically conductive via-hole 25 and the electrically conductive connection pad on the package substrate 10 are connected, thereby achieving electrical connection between the package substrate 10 and the PCB 20. In another example embodiment, the accommodating space extends through the upper and lower surfaces of the PCB 20. The packaging area 11 and/or an electrically conductive connection pad may be manufactured on the lower surface of the package substrate 10. Meanwhile, a connection portion and its electrically conductive via-hole may be manufactured at the lower opening of the accommodating space.

A method for manufacturing the connection portion 28 includes the following steps. A low-flow adhesive sheet (i.e., low-flow PP), which is a prepreg layer, is provided. A first window is formed in the low-flow adhesive sheet to expose the solder pads (the packaging area 11) on the package substrate 10. The aforementioned low-flow adhesive sheet is stacked onto the PCB 20. A release film is filled in the first window of the low-flow adhesive sheet to protect the solder pads. A substack 29 of the PCB 20 is provided. The substack 29 includes one or more core layers. The core layer here refers to Copper Clad Laminate (CCL). The substack 29 of the PCB 20 is laminated onto the aforementioned low-flow adhesive sheet. A second window is formed in the substack 29 of the aforementioned PCB 20. The position and the size of the second window are the same as those of the aforementioned first window. The release film is removed to expose the solder pads of the package substrate 10. Chip solder pads (i.e., surface mount solder pads) and gold contact fingers are manufactured on the substack 29 of the PCB 20. The chip solder pads are used for the installation of the surface-mount component 40. In the aforementioned step of manufacturing the second window on the substack 29 of the PCB 20, the substack 29 of the PCB 20 may be laminated onto the low-flow adhesive sheet before the second window is formed using a controlled deep milling groove method, or the second window may be formed in the substack 29 of the PCB 20 before the substack 29 of the PCB 20 is laminated onto the low-flow adhesive sheet.

In the example embodiments illustrated in FIGS. 10 and 11, the package substrate 10 is a cuboid. In other example embodiments, the package substrate 10 may be formed as a step block or may have another shape. In the hybrid carrier board 2000″ according to a variation of the second example embodiment as illustrated in FIG. 12, the upper surface of the package substrate 10 has a first step surface 15 and a second step surface 16, and the lower surface of the package substrate 10 is a flat surface. The first step surface 15 serves as the packaging area 11 and has solder pads disposed thereon. The second step surface 16 has one or more electrically conductive connection pads disposed thereon. The accommodating space of the PCB 20 is a blind slot that includes a slot bottom and a slot sidewall. The connection portion 28 of the PCB 20 is laminated onto the second step surface 16 of the package substrate 10. The first step surface 15 is exposed to serve as the packaging area 11. This connection portion 28 has an electrically conductive via-hole 25 disposed therein to electrically connect the PCB 20 and the package substrate 10. Meanwhile, another electrically conductive via-hole 25 may be configured at the slot bottom to electrically connect the PCB 20 and the package substrate 10. In the example embodiment illustrated in FIG. 12, the first step surface 15 is higher than the second step surface 16. In an alternative example embodiment, the first step surface 15 may be lower than the second step surface 16. The lower surface of the package substrate 10 may be a flat surface, or, alternatively, the lower surface of the package substrate 10 may have at least two step surfaces. When the lower surface of the package substrate 10 has two step surfaces, the aforementioned accommodating space has an upper opening and a lower opening that extend through the upper and lower surfaces of the PCB 20 respectively. Similarly, a connection portion of the PCB 20 may be disposed at the lower surface (the lower opening) of the package substrate, and the connection portion may have an electrically conductive via-hole disposed therein to electrically connect the package substrate 10 and the PCB 20.

The manufacturing process of the hybrid carrier board 2000″ illustrated in FIG. 12 is described as follows. The package substrate 10 and the PCB 20 are provided. The first step surface 15 and the second step surface 16 are manufactured on the package substrate 10. Solder pads are manufactured on the first step surface 15 to serve as the packaging area 11. An electrically conductive connection pad is manufactured on the second step surface 16. The solder pads and the electrically conductive connection pad are electrically connected. A blind slot is formed in the PCB 20 to serve as the accommodating space. The aforementioned package substrate 10 is laminated into the blind slot such that the second step surface 16 of the package substrate 10 is even with the upper surface of the PCB 20. A prepreg layer is provided. A first window is formed in the prepreg layer. The first window is larger than, or has the same size as, the aforementioned first step surface. The prepreg layer is stacked onto the PCB 20 and the second step surface 16 of the package substrate 10. The substack 29 of the PCB 20 is provided. A second window is formed in the substack 29 of the PCB 20. The position and the size of the second window is the same as those of the first window. The substack 29 of the PCB 20 is laminated onto the aforementioned prepreg layer. Chip solder pads and gold contact fingers are manufactured on the substack 29 of the PCB 20. The chip solder pads are used for the installation of a surface-mount component 40. The electrically conductive via-hole 25 is formed in the portion of substack 29 of the PCB 20 that is laminated to the second step surface 16 of the package substrate 10 (i.e. the connection portion 28) such that the electrically conductive via-hole 25 and the electrically conductive connection pad on the second step surface 16 are connected, thereby achieving electrical connection between the package substrate 10 and the PCB 20.

In the aforementioned example embodiment, the electrical connection between the package substrate 10 and the PCB 20 may alternatively be achieved by means of an electrically conductive layer formed on a sidewall of the package substrate 10. Specifically, a side electrically conductive layer is disposed on the sidewall of the package substrate 10. An electrically conductive layer or a circuit of the package substrate 10 is electrically connected to the side electrically conductive layer. At the same time, the side electrically conductive layer is also electrically connected to an electrically conductive layer (for example, the copper of the core layer) of the PCB 20, thereby achieving electrical connection between the package substrate 10 and the PCB 20.

In another example embodiment, the accommodating space may alternatively have a side opening extending through a sidewall of the PCB 20. The cross section of the package substrate 10 along a plane parallel to the surface of the PCB 20 may be a rectangle, square, triangle, “T” shape, “L” shape, “+” shape, or another shape such as an irregular shape.

In the aforementioned carrier boards or methods for manufacturing the carrier boards, the number of layers in the package substrate 10 and the number of layers in the PCB 20 may be designed to be one or more according to actual circuit and thickness requirements. The numbers of the first electrically conductive via-holes and the second electrically conductive via-holes may be designed to be one or more according to actual stacking.

The embodiments of present disclosure provide the following benefits. Bare dies and electronic components are both installed on one carrier board, and each electronic chip or optoelectronic chip may be directly installed as a bare die. Therefore, the area of the carrier board can be effectively reduced, thus significantly increasing the level of integration for the optical module. Manufacturing techniques for package substrates and PCBs are combined, and the package substrate is laminated into the PCB. A local area of the carrier board according to the embodiments of the present disclosure has high precision traces and a coefficient of thermal expansion (CTE) matching that of the bare die, and is capable of meeting the requirements for packaging an optoelectronic bare die; other areas of the carrier board have high peel strength and high plugging and unplugging reliability. At the same time, the optical module including the carrier board according to the embodiments of the present disclosure has a simple and short high-speed link, which increases high-frequency bandwidth and effectively reduces the height of the assembly as a whole and lowers the cost.

The series of detailed descriptions above is only intended to provide specific descriptions of feasible embodiments of the present disclosure. They are not to be construed as limiting the scope of protection for the present disclosure; all equivalent embodiments or changes that are not detached from the techniques of the present disclosure in essence should fall under the scope of protection of the present disclosure.

What is claimed is:

1. A hybrid carrier board, comprising:
a printed circuit board (PCB); and
a package substrate bonded to, and electrically connected with, the PCB,
wherein a surface of the package substrate is partially exposed outside of the PCB to form a packaging area adapted for bare die installation.

2. The hybrid carrier board of claim 1, wherein solder pads are disposed on the packaging area, and
a pitch of the solder pads on the packaging area matches a pitch of solder pads of a bare die that is to be installed.

3. The hybrid carrier board of claim 2, wherein the pitch between the solder pads on the packaging area is less than or equal to 150 μm.

4. The hybrid carrier board of claim 1, wherein the package substrate comprises a dielectric layer and an electrically conductive layer, a coefficient of thermal expansion (CTE) of the dielectric layer being smaller than or equal to a CTE of an insulating layer of the PCB.

5. The hybrid carrier board of claim 4, wherein the CTE in a horizontal direction of the dielectric layer is less than or equal to 10 ppm/° C.

6. The hybrid carrier board of claim 5, wherein a material of the dielectric layer of the package substrate is ceramic, glass, or silicon, or
the material of the dielectric layer of the package substrate and the material of the insulating layer of the PCB are both Bismaleimide Triazine (BT) resin or BT-like resin.

7. The hybrid carrier board of claim 1, wherein an electrical interface is disposed on a surface of the PCB.

8. The hybrid carrier board of claim 1, wherein surface-mount solder pads are disposed on a surface of the PCB, the surface-mount solder pads being adapted for surface-mount component installation.

9. The hybrid carrier board of claim 1, wherein the package substrate and the PCB are bonded together by means of lamination.

10. The hybrid carrier board of claim 9, wherein the PCB comprises a first substack and a second substack, the first substack and second substack being disposed on an upper surface and a lower surface of the package substrate, respectively.

11. The hybrid carrier board of claim 10, wherein a window is disposed in the first substack and/or the second substack to expose a portion of the upper surface and/or lower surface of the package substrate to serve as the packaging area.

12. The hybrid carrier board of claim 10, wherein an electrically conductive via-hole is disposed in the first substack and second substack, the electrically conductive via-hole being used to electrically connect the PCB and package substrate.

13. A method for manufacturing a hybrid carrier board, the method comprising:
manufacturing a package substrate, the package substrate comprising an insulating dielectric layer and an electrically conductive layer;
forming a packaging area on a surface of the package substrate, the packaging area having formed thereon solder pads adapted for bare die installation;
providing a substack of a printed circuit board (PCB);
laminating the package substrate and the substack of the PCB together and exposing the packaging area; and
manufacturing an electrically conductive via-hole to electrically connect the substack of the PCB and the package substrate.

14. The manufacturing method of claim 13, wherein the method for laminating the package substrate and the substack of the PCB together and exposing the packaging area comprises:
providing a prepreg layer, and forming a first window in the prepreg layer, a position and a size of the first window corresponding to the packaging area;
stacking the prepreg layer on a surface of the package substrate where the substack of the PCB is to be laminated, and filling a release film in the first window;
laminating the substack of the PCB onto the prepreg layer;
forming a second window in the substack of the PCB, a position and a size of the second window being the same as the position and the size of the first window; and
removing the release film to expose the packaging area.

15. The manufacturing method of claim 14, wherein the method for forming the second window comprises controlled deep milling.

16. The manufacturing method of claim 13, wherein the method for laminating the package substrate and the substack of the PCB together and exposing the packaging area comprises:
providing a prepreg layer, and forming a first window in the prepreg layer, a position and a size of the first window corresponding to the packaging area;
stacking the prepreg layer on the surface of the package substrate where the substack of the PCB is to be laminated, and filling a release film in the first window;
forming a second window in the substack of the PCB, a position and a size of the second window being the same as the position and the size of the first window;
laminating the substack onto the prepreg layer; and
removing the release film to expose the packaging area.

17. The manufacturing method of claim 14, wherein the prepreg layer is a low-flow prepreg.

18. An optical module, comprising:
a bare die comprising a photonic integrated circuit; and
the hybrid carrier board of claim 1,
wherein the bare die is installed on the packaging area of the hybrid carrier board.

19. The optical module of claim 18, wherein the bare die is installed on the packaging area of the hybrid carrier board by means of flip-chip technology and/or wire bonding.

20. An assembly, comprising:
a bare die; and
the hybrid carrier board of claim 1,
wherein the bare die is installed on the packaging area of the hybrid carrier board.

21. The assembly of claim 20, wherein the assembly further comprises an electronic component and/or a packaged semiconductor chip, and the electronic component and/or packaged semiconductor chip is installed on the PCB of the hybrid carrier board.
